(19) United States
(12) Patent Application Publication
(10) Pub. No.: US 2016/0379953 A1
(43) Pub. Date: Dec. 29, 2016

(54) SEMICONDUCTOR WIRE BONDING AND METHOD

(71) Applicant: Texas Instruments Incorporated, Dallas, TX (US)

(72) Inventors: Patrick Francis Thompson, Wylie, TX (US); Jeffrey Alan West, Dallas, TX (US); Thomas D. Bonifield, Dallas, TX (US); Fu-Kang Hsu, New Taipei City (TW); Ching-Lun Hsia, Taoyuan City (TW)

(21) Appl. No.: 14/749,219

(22) Filed: Jun. 24, 2015

(51) Int. Cl. H01L 23/00

(52) U.S. Cl. CPC H01L 24/48; H01L 24/85; H01L 24/08; H01L 24/73; H01L 24/16; H01L 2224/05647; H01L 2224/0401; H01L 2224/04042; H01L 2224/04073; H01L 2224/16055

(57) ABSTRACT

Circuitry is disclosed that includes a first conductive portion of a first die and a first conductive pillar electrically and physically connected to the first conductive portion. The first conductive pillar includes a first conductive pillar surface. A first bond connects the first conductive pillar surface to a first end of a bond wire.

### BACKGROUND

High voltage circuits are being manufactured smaller and are required to operate at higher voltages. The smaller circuits cause conductors of different potentials to be located proximate each other. The close proximity of conductors of different potentials combined with the higher voltages increases the voltage gradients between the conductors. The higher voltage gradients degrade the device performance.

### SUMMARY

Circuitry is disclosed that includes a conductive portion of a die and a conductive pillar electrically and physically connected to the conductive portion. The conductive pillar includes a conductive pillar surface. A bond connects the conductive pillar surface to an end of a bond wire.

### BRIEF DESCRIPTION OF THE DRAWINGS

FIG. 1 is a side elevation view of prior art circuitry having a bond wire connected between two conductors.

FIG. 2 is a side elevation view of an embodiment of circuitry having an elevated bond wire bonded to conductive pillars.

FIG. 3 is an expanded elevation view of the first conductive pillar of FIG. 2.

FIG. 4 is an expanded elevation view of the second conductive pillar of FIG. 2.

FIG. 5 is a flow chart describing a method for fabricating the circuitry of FIG. 2.

### DETAILED DESCRIPTION

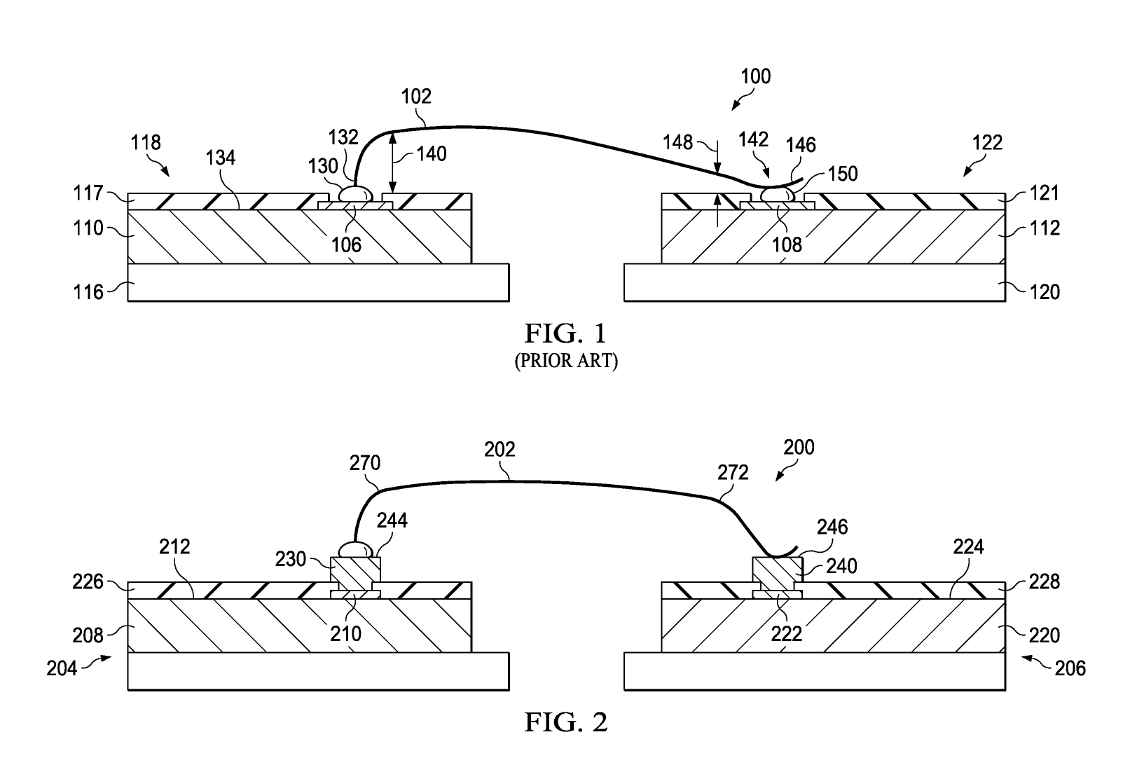

FIG. 1 is a side elevation view of prior art circuitry 100 having a bond wire 102 connected between a first pad 106 and a second pad 108. The first pad 106 is a conductive portion of a first die 110 and the second pad 108 is a conductive portion of a second die 112. The first die 110 is located on or attached to a first substrate 116. A first dielectric material 117 covers at least a portion of the first die 110 and may cover at least a portion of the first pad 106. The first substrate 116 may have other dies located thereon, which are not shown in FIG. 1. The first die 110, the first substrate 116, and components attached thereto constitute a first circuit 118. The second die 112 is located on or attached to a second substrate 120. A second dielectric material 121 covers at least a portion of the second die 112 and may cover at least a portion of the second pad 108. The second substrate 120 may have other dies located thereon, which are not shown in FIG. 1. The second die 112, the second substrate 120, and components attached thereto constitute a second circuit 122. Both the first die 110 and the second die 112 may have conductors (not shown) located thereon that are at different electric potentials than the electric potential of the bond wire 102. In other examples, the first circuit 118 and the second circuit 122 may have conductors (not shown) located thereon that are at different electric potentials than the bond wire 102.

The bond wire 102 is bonded to the first pad 106 by way of a ball bond 130. The ball bond 130 enables an end portion 132 of the bond wire 102 next to the ball bond 130 to have a steep angle. The steep angle causes the end portion 132 of the bond wire 102 to intersect the ball bond 130 substantially perpendicular relative to the surface 134 of the first die 110. The steep angle enables the portion of the bond wire 102 extending over the first die 110 to be located a distance 140 from the surface of the dielectric material 117, wherein the distance 140 is relatively large. The bond wire 102 is bonded to the second pad 108 by way of a stitch bond 142. In many fabrication applications, one end of a bond wire is bonded by way of a ball bond and the other end is bonded by way of a stitch bond. The stitch bond 142 does not provide for the steep angle in an end 146 of the bond Wire 102 as provided by the ball bond 130 because a steep angle at the stitch bond 142 may lead to failure of the stitch bond 142. Accordingly, the distance 148 between the second die 112 and the bond wire 102 is relatively small and the portion of the bond wire 102 located over the second die 112 is relatively close to the second die 112.

The stitch bond 142 shown in FIG. 1 is referred to a stitch on ball bond (SBB). A ball 150 is fabricated on the pad 108 and the bond wire 102 is stitch bonded to the ball 150. The height of the ball 150 lifts the stitch bond 142 so that the bond wire 102 proximate the second dielectric material 121 does not contact and/or has additional clearance above the second dielectric material 121 or other components (not shown) on the second die 112. In some applications, the additional height of the ball 150, the height 148 of the bond wire 102 is not great enough to sufficiently reduce the voltage gradient between the second circuit 122 and the bond wire 102 to operate the circuitry 100 at high voltage. More specifically, the bond wire 102 may not be located far enough away from conductors in the second die 112 to prevent degradation in the performance of the circuitry 100. In addition, the stitch bond 146 is located at the top of the ball 150, which is a more difficult and expensive bond to create than a standard stitch bond fabricated onto a flat surface.

Device geometries, such as those in the circuitry 100, are becoming smaller and operating at higher voltages. The smaller devices cause the bond wire 102 to be located closer to critical areas of the first die 110 and the second die 112, which puts the bond wire 102 in close proximity to conductors (not shown) on or in the first and second dies 110 and 112. The higher voltage in the circuitry 100 causes higher voltage gradients between the bond wire 102 and the first and second dies 110 and 112. The voltage gradients become even higher as the distances 140 and 148 become smaller and the circuitry 100 is made smaller. The combination of the higher voltages and the smaller distances 140 and 148 results in higher voltage gradients between the bond wire 102 and the first and second dies 110 and 112. These higher voltage gradients degrade the performance of the circuitry 100. For example, the high voltage gradients cause shorts and/or arcs through an encapsulant material (not shown) between the bond wire 102 and conductors (not shown) located in the first and second dies 110 and 112.

The circuitry and methods described herein overcome the above-described problems with high voltage gradients by the addition of pillars that raise the bond wire higher over conductors located in or on circuits proximate the bond wire. The raised bond Wile is further from conductors on and in the dies, so the circuitry can withstand higher voltages. Reference is made to FIG. 2, which is a side elevation view of circuitry 200. The circuitry 200 has a bond wire 202 connected between a first circuit 204 and a second circuit 206. The first circuit 204 has a first die 208 that has a first conductive pad 210 fabricated on a surface 212. The first conductive pad 210 is a conductive portion of the first die 208. The first die 208 may have other conductors (not shown in FIG. 2) located in or on the first die 208, wherein the other conductors operate at different potentials than the bond wire 202. The second circuit 206 has a second die 220 that has a second conductive pad 222 fabricated on a surface 224. The second conductive pad 222 is a conductive portion of the second die 220. The second die 220, like the first die 208, may have other conductors (not shown in FIG. 2) located in or on the second die 220, wherein the other conductors operate at different potentials than the bond wire 202.

The first circuit 204 has a first dielectric material 226 applied to the surface 212 of the first die 208 and the second circuit 206 has a second dielectric material 228 applied to the surface 224 of the second die 220. A first conductive pillar 230 is fabricated onto the first pad 210 and a second conductive pillar 240 is fabricated onto the second pad 222. The first and second conductive pillars 230 and 240 may extend onto the first and second dielectric materials 226 and 228 such that they are wider than their respective first and second conductive pads 210 and 222. For example, the first conductive pillar 230 has a top surface 244 that has an area that may be greater than the area of the conductive pad 210. Likewise, the second conductive pillar 240 has a top surface 246 that has an area that may be greater than the area of the second conductive pad 222. Accordingly, small conductive pads 210 and 222 conduct between the pillars 230 and 240 and the dies 208 and 220, wherein the pillar surfaces 244 and 246 are large. These smaller conductive pads 210 and 222 decrease the capacitances to underlying circuitry and enable more room for conductors to be routed. The pillars 230 and 240 further enable the conductive pads 210 and 222 to be located close to the edges of the dies 204 and 206. For example, the larger surfaces 244 and 246 enable the bonds attached thereto to be located close to the edges of the dies 208 and 220. In some examples, the diameter of the pillars 230 and 240 narrows proximate the dielectric materials 226 and 228 so that the openings in the dielectric materials 226 and 228 are larger than the diameters of the pillars 230 and 240 in those locations.

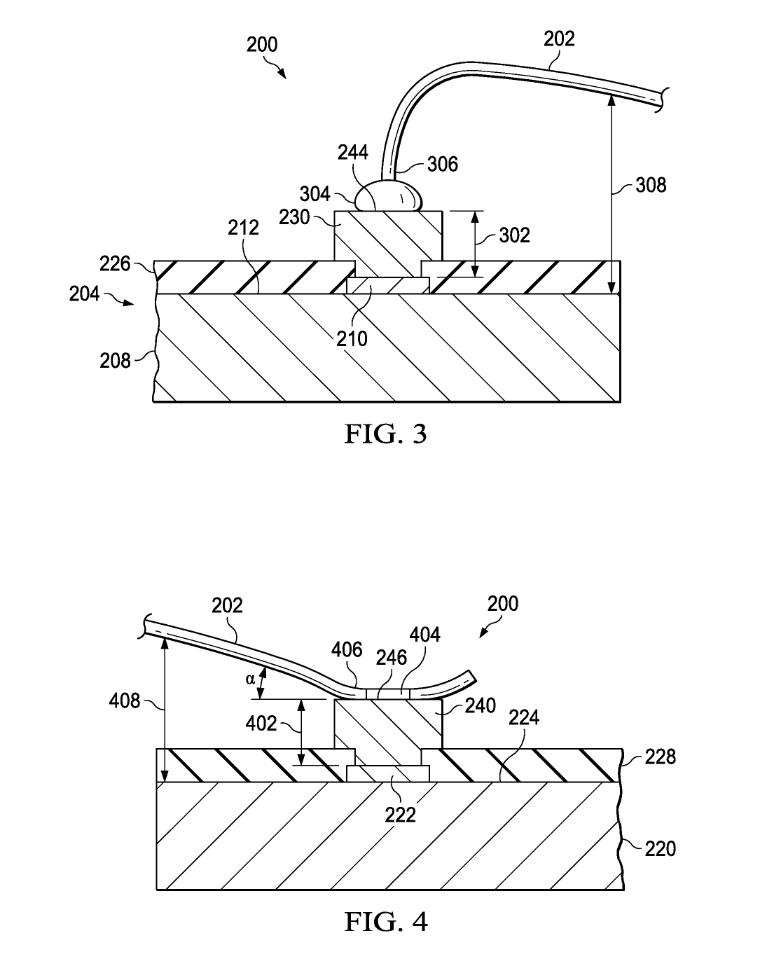

FIG. 3 is an expanded elevation view of the first conductive pillar 230. The elements in FIG. 3 may not be in scale for illustration purposes. The pillar 230 has a surface 244 and extends to a height 302 between the first pad 210 and the surface 244. In some embodiments, the height 302 is 25um to 75um and in other embodiments, the height 302 is approximately 35 um. A ball bond 304 connects an end 306 of the bond wire 202 to the surface 244 of the pillar 230. The pillar 230 raises the distance 308 between the bond wire 202 and the surface 212 of the die 208 by the height 302 or by an amount substantially the same as or proportional to the height 302. In some embodiments, the height 308 is between 180 um and 200 um and in other embodiments the height 308 is approximately 250-350 um. The height 308 enables the circuitry 200 to operate at higher voltages than conventional circuitry that does not include the pillar 230 by moving the bond wire 202 away from the first die 208. As shown, the area of the surface 244 of the first pillar 230 is greater than the area of the first conductive pad 210. Accordingly, the larger surface area provides a greater target for a machine that fabricates the ball bond 304. The target area for the machine is not dependent on the area of the first pad 210.

FIG. 4 is an expanded elevation view of the second conductive pillar 240. The elements in FIG. 4 may not be in scale for illustration purposes. The pillar 240 has a surface 246 and extends to a height 402 between the second pad 222 and the surface 246. In some embodiments, the height 402 is 25 um to 75 um and in other embodiments, the height 402 is approximately 35 um. A stitch bond 404 connects an end 406 of the bond wire 202 to the surface 246 of the pillar 240. The pillar 240 raises the distance 408 between the bond wire 202 and the surface 224 of the die 220 by the height 402 or by an amount substantially the same as or proportional to the height 402. In some embodiments, the height 408 is between 180 um and 200 um and in other embodiments the height 408 is between 250 um and 350 um. The height 408 enables the circuitry 200 to operate at higher voltages than conventional circuitry that does not include the pillar 240 by moving the bond wire 202 away from the second die 220. As shown, the area of the surface 246 of the second pillar 240 is greater than the area of the second conductive pad 222. Accordingly, the larger surface area provides a greater target area for a machine that fabricates the stitch bond 404. The target area for the machine is not dependent on the area of the second pad 222. In addition, the stitch bond 404 is now located a distance from the second dielectric material 228, so there is less chance of any interference between the bond wire 202 and the second dielectric material 228.

The stitch bond 404 results in a low angle a between the bond wire 202 and the surface 246 of the second pillar 240. Therefore, without the additional height provided by the second pillar 240, the height 408 would be low, which results in the bond wire 202 being in close proximity to the die 220 and/or conductors (not shown) located on or in the die 220. The low height creates a high voltage gradient between the bond wire 202 and the conductors on the surface 224 or within the die 220, which eventually may cause degradation in the performance of the die 220 and/or the circuitry 200. It is noted that the distance between the first and second dies 208 and 220 and the bond wire 202 has increased in all locations, not just where the heights 308 and 408 are shown. Therefore, the additional height provided by the first and second pillars 230 and 240 increases the distance between the bond wire 202 and all the conductors in and on the first and second dies 208 and 220. Furthermore, no stitch on ball bond (SBB) is required because the pillars 230 and 240 provide the additional height of the SBB or greater height than provided by the SBB. The pillars 230 and 240 also provide a more robust target for the stitch bonds which improves the yields of the bonds. Both the elimination of the SSB and the higher yields reduce the costs of the dies.

The pillars 230 and 240 may be fabricated from virtually any conductive material, such as copper, nickel, gold, and aluminum. In some embodiments, the pillars 230 and 240 are fabricated by an electroplating process. In some embodiments, the first and second pillars 230 and 240 are fabricated directly onto the first and second dies 208 and 220 and not on the first and second conductive pads 210 and 222. For example, the first and second pillars 230 and 240 may be fabricated on other conductive portions of the first and second dies 208 and 220. The pads 210 and 222 have been described herein as being conductive pads or bonding pads on the surfaces of dies. In some embodiments, the pads 210 and 222 are plates of capacitors, such as galvanic isolators. Accordingly, the pillars 230 and 240 are fabricated onto the plates of the capacitors.

The bond wire 202 may be formed into a bent profile before bonding that causes it to rise, especially proximate the stitch bond 404 so as to provide maximum heights 308 and 408. Referring to FIG. 2, the bond wire 202 has. a first kink 270 at a location that is 10% from the first pillar 230 and a second kink 272 that is between 80% and 90-% from the first pillar 230. In some embodiments, the second kink 272 is located at 85% from the first pillar. The placement of the second kink 272 enables the bond wire 202 to be at least partially symmetric, which enables approximately the same isolation with first and second dies 204 and 206.

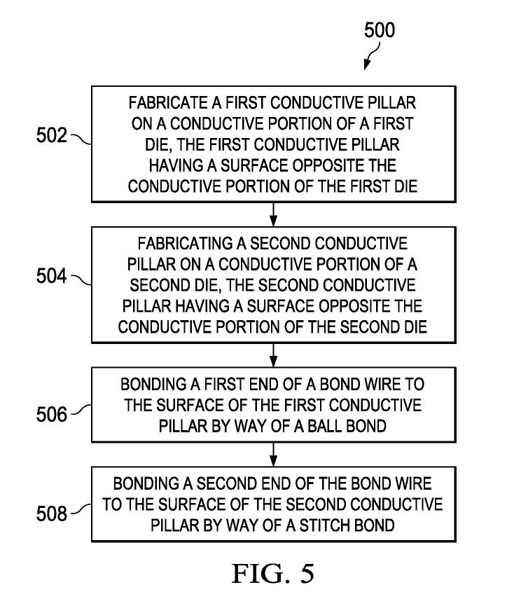

A method for fabricating the circuit 200 is described by the flow chart 500 of FIG. 5. At step 502, the method includes fabricating a first conductive pillar on a conductive portion of a first die, the first conductive pillar having a surface opposite the conductive portion of the first die. At step 504, the method includes fabricating a second conductive pillar on a conductive portion of a second die, the second conductive pillar having a surface opposite the conductive portion of the second die. At step 506, the method includes bonding a first end of a bond wire to the surface of the first conductive pillar by way of a ball bond. At step 508, the method includes bonding a second end of the bond wire to the surface of the second conductive pillar by way of a stitch bond.

Certain embodiments of dies and die fabrication methods have been expressly described in detail herein. Alternative embodiments will occur to those skilled in the art after reading this disclosure. The claims are intended to be broadly construed to cover all such alternative embodiments, except as limited by the prior art.

1-25. (canceled)

26. A circuit comprising:
a die;
a bond pad on the die;
a dielectric layer on the die, covering a portion of the bond pad, the dielectric layer including an opening defining a surface of the bond pad;
a conductive pillar connected to and extending from the surface of the bond pad, the conductive pillar having a height;
a bond on a surface of the conductive pillar; and
a bond wire connected to the bond, wherein an area of the surface of the conductive pillar is larger than an area of the surface of the bond pad.

27. The circuit of claim 26, wherein the bond is a ball bond.

28. The circuit of claim 26, wherein the bond is a stitch bond.

29. The circuit of claim 26, wherein the conductive pillar has a generally rectangular cross section parallel to the surface of the bond pad.

30. The circuit of claim 26, wherein the conductive pillar extends perpendicularly from the surface of the bond pad.

31. The circuit of claim 26, wherein conductive pillar is a metal selected from a group consisting of copper, nickel, gold and aluminum.

32. The circuit of claim 26, wherein the die is on a substrate.

33. The circuit of claim 26, wherein the height is 25 μm to 75 μm.

34. The circuit of claim 26, wherein the surface of the conductive pillar is greater than the surface of the bond pad.

35. The circuit of claim 26 further comprising a mold compound encapsulating portions of the die, the bond wire and the conductive pillar.

36. A circuit comprising:
a first die and a second die;
a first bond pad on the first die and a second bond pad on the second die;
a first dielectric layer on the first die covering a portion of the first bond pad, the first dielectric layer including a first opening defining a first surface of the first bond pad;
a first conductive pillar connected to and extending from the first surface of the first bond pad;
a second dielectric layer on the second die covering a portion of the second bond pad, the second dielectric layer including a second opening defining a second surface of the second bond pad;
a second conductive pillar connected to and extending from the second surface of the second bond pad; and
a bond wire including a first end and a second end, the first end connected to a first surface of the first conductive pillar via a first bond and a second end connected to a second surface of the second conductive pillar via a second bond.

37. The circuit of claim 36, wherein the first bond is a ball bond.

38. The circuit of claim 36, wherein the second bond is one of a ball bond and a stitch bond.

39. The circuit of claim 36, wherein an area of the first surface of the first conductive pillar is larger than an area of the first surface of the first bond pad.

40. The circuit of claim 36, wherein an area of the second surface of the second conductive pillar is larger than an area of the second surface of the second bond pad.
